(19) United States
(12) Patent Application Publication
(10) Pub. No.: US 2024/0078282 A1
(43) Pub. Date: Mar. 7, 2024

(54) CONJUGATE GRADIENT ACCELERATION APPARATUS USING BAND MATRIX COMPRESSION IN DEPTH FUSION TECHNOLOGY

(71) Applicant: Korea Advanced Institute of Science and Technology, Daejeon (KR)

(72) Inventors: Hoi Jun YOO, Daejeon (KR); Dong Seok IM, Daejeon (KR)

(73) Assignee: Korea Advanced Institute of Science and Technology, Daejeon (KR)

(21) Appl. No.: 18/139,952

(22) Filed: Apr. 27, 2023

(30) Foreign Application Priority Data
Apr. 29, 2022 (KR) 10-2022-0053836

(51) Int. Cl. G06F 17/16; G06T 7/521

(52) U.S. Cl. CPC G06F 17/16; G06T 7/521; H04N 19/174

(57) ABSTRACT

Disclosed is a conjugate gradient acceleration apparatus using band matrix compression in depth fusion technology including a band matrix conversion unit configured to convert an adjacency matrix for correcting depth data acquired from data of an image sensor through deep learning based on depth information acquired from a depth sensor into a band matrix using rows of the adjacency matrix as addresses of query points and columns of the adjacency matrix as the nearest neighbors at the query points, a band matrix compression unit configured to mark an index on each band in order to compress the band matrix and to compress data, a memory unit configured to store tile data of the band matrix, and a band matrix calculation unit configured to perform computation of the band matrix and a transposed band matrix or computation of a symmetric band matrix with respect to the band matrix and a vector.

### BACKGROUND OF THE INVENTION

### Field of the Invention

The present invention relates to a conjugate gradient acceleration apparatus using band matrix compression in depth fusion technology, and more particularly to a conjugate gradient acceleration apparatus using band matrix compression in depth fusion technology that proposes a new efficient sparse matrix compression method and an efficient sparse matrix computation method in consideration of a problem in that very large and very sparse matrix computation is inefficient on conventional hardware.

### Description of the Related Art

Depth fusion technology, which is technology for combining a depth sensor configured to acquire depth information and an image sensor configured to acquire two-dimensional RGB information, is capable of more accurately extracting 3D RGB information. Depth fusion technology may be applied to AR/VR applications, autonomous driving applications, robotic automation, etc.

A depth sensor, such as a time-of-flight (ToF) sensor, emits laser light, detects light reflected by an object, and measures the difference in time or wavelength between the emitted light and the reflected light to acquire depth data.

Since the depth sensor requires power necessary to emit light and power necessary to detect reflected light, however, power consumption of the depth sensor is great, and therefore it is difficult to use the depth sensor in a mobile device equipped with a battery (Reference Document 1).

Furthermore, when a target object is very distant, is very close, is made of a transparent material, or is made of a material that exhibits high reflectance, it is not possible for the depth sensor to detect the depth of a relevant area.

Consequently, it is necessary to acquire more accurate and robust depth information through additional use of an image sensor, instead of depending only on the depth sensor in order to extract depth information. In recent years, much research on a method of training a deep learning circuit using RGB images acquired from the image sensor as input and already known RGB+depth information as a true value and inputting data of the image sensor into the trained deep learning circuit to acquire RGB+depth information has been conducted (Reference Document 2).

However, the depth information thus acquired may become inaccurate during use thereof depending on the shape and disposition of the target object or environmental conditions, such as image background and illuminance, whereby it is difficult to actually utilize the depth information.

Depth fusion technology is technology of finding a weight adjacency matrix of A from depth information x0 acquired through deep learning and, on the assumption that the depth result is x when x0 is updated with a result value of the ToF sensor, acquiring the value of x, which is the optimal solution that minimizes an energy model ∥x−Ax∥² using a conjugate gradient method (Reference Document 3).

Since the adjacency matrix A is very large (703 MB) and data in the matrix are sparse (scarcity of 99.8%), however, data is used in a compressed state, whereby it is possible to reduce the amount of memory used to store the data. If a conventional sparse matrix is compressed without change, however, compression efficiency is low, and therefore a separate method capable of increasing the compression rate is needed.

Furthermore, the conjugate gradient method is generally used in order to find the solution to the above complicated equation. Computations to perform the conjugate gradient method include multiplication between matrices using the adjacent matrix described above and multiplication between a matrix and a vector. In these computations, the amount of data that are moved is large and the movement of data is irregular, whereby data access to a memory is increased, and therefore the overall computation speed is low.

### PRIOR ART DOCUMENTS

### Non-Patent Documents

(Non-Patent Document 0001) Reference Document 1: Intel, LIDAR CAMERA L515, ?lt; https://www.intelrealsense.com/lidar-camera-1515>
(Non-Patent Document 0002) Reference Document 2: J. Bian et al., DEPTH AND EGO-MOTION LEARNING FROM MONOCULAR VIDEO
(Non-Patent Document 0003) Reference Document 3: Y. You et al., DEPTH FOR 3D OBJECT DETECTION IN AUTONOMOUS DRIVING

### SUMMARY OF THE INVENTION

The present invention has been made in view of the above problems, and it is an object of the present invention to provide a conjugate gradient acceleration apparatus using band matrix compression in depth fusion technology capable of acquiring depth information that is accurate and more robust to environmental change and the shape, disposition, and background of a target object based on a detailed structure of depth fusion technology of combining RGB+depth information acquired from an image and the depth result of a depth sensor.

It is another object of the present invention to provide a conjugate gradient acceleration apparatus using band matrix compression in depth fusion technology capable of performing depth fusion even though the resolution and the number of pixels of the depth sensor do not coincide with an output image of an image sensor.

It is another object of the present invention to provide a conjugate gradient acceleration apparatus using band matrix compression in depth fusion technology capable of always activating the depth sensor, such as a ToF sensor, based on purposes and power consumption conditions to receive depth information and performing depth fusion with the image sensor, performing a repetitive operation of activating the depth sensor for a predetermined time at predetermined intervals to periodically perform depth fusion and deactivating the depth sensor again, or activating the depth sensor as needed, for example when the depth sensor is initially energized so as to be used or when a user determines that it is necessary to use the depth sensor, to perform depth fusion.

It is another object of the present invention to provide a conjugate gradient acceleration apparatus using band matrix compression in depth fusion technology capable of providing a band matrix compression method and a band matrix calculation unit for accelerating a conjugate gradient method used when depth fusion is performed.

It is a further object of the present invention to provide a conjugate gradient acceleration apparatus using band matrix compression in depth fusion technology capable of accelerating multiplication between a band matrix and a transposed band matrix and multiplication between the band matrix and a vector through a dual algorithm of converting an adjacency matrix into the band matrix and efficiently accelerating the band matrix.

In accordance with the present invention, the above and other objects can be accomplished by the provision of a conjugate gradient acceleration apparatus using band matrix compression in depth fusion technology, the conjugate gradient acceleration apparatus including a band matrix conversion unit configured to convert an adjacency matrix for correcting depth data acquired from data of an image sensor through deep learning based on depth information acquired from a depth sensor into a band matrix using rows of the adjacency matrix as addresses of query points and columns of the adjacency matrix as the nearest neighbors at the query points, a band matrix compression unit configured to mark an index on each band in order to compress the band matrix converted by the band matrix conversion unit and to compress data in a state of being divided into a predetermined bit band index, predetermined bit nonzero ingredient data, and another predetermined bit nonzero ingredient index, a memory unit configured to store tile data of the band matrix, and a band matrix calculation unit configured to perform computation of the band matrix and a transposed band matrix or computation of a symmetric band matrix with respect to the band matrix and a vector.

The band matrix compression unit may perform compression to remove a value of 0 from matrix ingredients belonging to bands of the band matrix through run-length encoding.

The band matrix calculation unit may perform computation of the band matrix and computation of the transposed band matrix in units of a tile and may reuse data by using a routing register array through outer-product computation between tiles, which multiplies the tiles, without memory access.

When the band matrix and the transposed band matrix are computed, the band matrix calculation unit may compute ingredients in the tiles by reusing middle data in the routing register array through inner-product computation.

The band matrix calculation unit may perform computation of the symmetric band matrix with respect to the band matrix and the vector in units of a tile and may reuse data by using a routing register array through outer-product computation between tiles, which multiplies the tiles, without memory access.

When the symmetric band matrix and the vector are computed, the band matrix calculation unit may compute ingredients in the tiles by reusing middle data in the routing register array through inner-product computation.

The band matrix calculation unit may always activate the depth sensor based on purposes and power consumption conditions to receive depth information in order to perform depth fusion with the image sensor, may activate the depth sensor for a predetermined time at predetermined intervals to periodically perform depth fusion, or may intermittently activate the depth sensor as needed to perform depth fusion.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a block diagram showing a conjugate gradient acceleration apparatus using band matrix compression in depth fusion technology according to the present invention;

FIG. 2 is a view showing a window-unit k-nearest neighbor algorithm to convert an adjacency matrix into a band matrix and a method of compressing the band matrix in the conjugate gradient acceleration apparatus using band matrix compression in depth fusion technology;

FIG. 3 is a view illustrating a computation method when the band matrix is multiplied by a transposed band matrix through a band matrix calculation unit and the effect thereof in the conjugate gradient acceleration apparatus using band matrix compression in depth fusion technology;

FIGS. 4 and 5 are views illustrating a computation method when the band matrix is multiplied by the transposed band matrix through a routing register array in the band matrix calculation unit in the conjugate gradient acceleration apparatus using band matrix compression in depth fusion technology;

FIG. 6 is a view illustrating a computation method when a symmetric band matrix is multiplied by a vector through the band matrix calculation unit and the effect thereof in the conjugate gradient acceleration apparatus using band matrix compression in depth fusion technology; and

FIG. 7 is a view illustrating a computation method when the symmetric band matrix is multiplied by the vector through the routing register array in the band matrix calculation unit in the conjugate gradient acceleration apparatus using band matrix compression in depth fusion technology.

### DETAILED DESCRIPTION OF THE INVENTION

It should be understood that the terms or words used in the specification and appended claims should not be construed as being limited to general and dictionary meanings, but should be construed based on meanings and concepts according to the technical idea of the present invention on the basis of the principle that the inventor is permitted to define appropriate terms for the best explanation.

Accordingly, embodiments described in this specification and constructions shown in the drawings are merely the most preferred embodiment of the present invention and do not speak for the entirety of the technical idea of the present invention, and therefore it should be understood that various replaceable equivalents and modifications may be possible at the time of filing the present application.

Hereinafter, a conjugate gradient acceleration apparatus using band matrix compression in depth fusion technology according to the present invention will be described in detail with reference to the accompanying drawings.

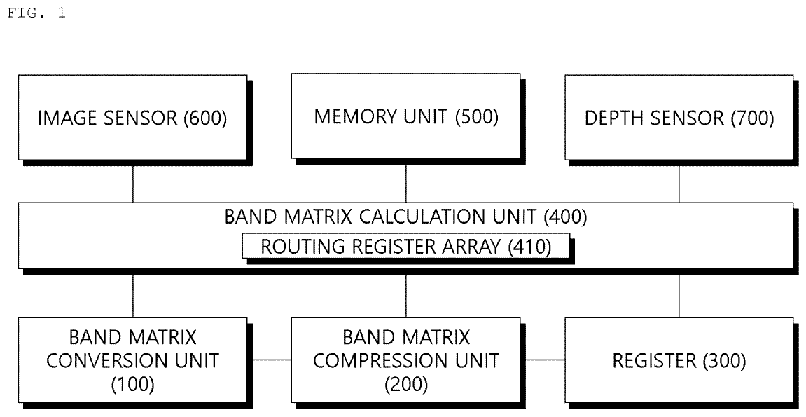

First, a conjugate gradient acceleration apparatus using band matrix compression in depth fusion technology according to the present invention will be described with reference to FIG. 1.

As shown in FIG. 1, the conjugate gradient acceleration apparatus using band matrix compression in depth fusion technology according to the present invention includes a band matrix conversion unit 100, a band matrix compression unit 200, a register 300, a band matrix calculation unit 400, and a memory unit 500.

The conjugate gradient acceleration apparatus using band matrix compression in depth fusion technology according to the present invention uses a method of correcting depth data acquired from data of an image sensor 600 through deep learning based on depth information acquired from a depth sensor 700 using an adjacency matrix, whereby it is possible to perform depth fusion with respect to the depth data acquired from the image sensor irrespective of the resolution of the depth sensor and the number of pixels.

First, depth fusion technology is technology for, on the assumption that the measurement value of a ToF sensor, which is the depth sensor 700, is x′ and an adjacency matrix denoted by A is given, calculating the value of x, which is the optimal solution of Mathematical Expression 1 below, using depth information acquired through deep learning as depth information x updated with the depth measurement value x′.

∥x−Ax∥² [Mathematical Expression 1]

(A: adjacency matrix, x: updated depth value)

The conjugate gradient acceleration apparatus using band matrix compression in depth fusion technology according to the present invention always activates the depth sensor 700 based on purposes and power consumption conditions to receive depth information and performs depth fusion with the image sensor 600 or performs a repetitive operation of activating the depth sensor 700 for a predetermined time at predetermined intervals to periodically perform depth fusion and deactivating the depth sensor 700 again, wherein the depth sensor is intermittently activated as needed to perform depth fusion.

The conjugate gradient acceleration apparatus using band matrix compression in depth fusion technology according to the present invention converts the adjacency matrix of Mathematical Expression 1 above into a band matrix, compresses the band matrix in order to accelerate computation of a conjugate gradient method used during depth fusion, and accelerates multiplication between the band matrix and a transposed band matrix and multiplication between the band matrix and a vector.

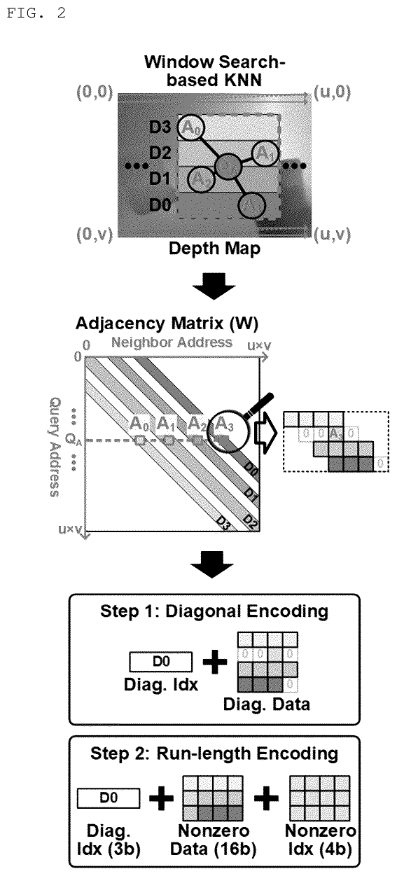

The adjacency matrix of Mathematical Expression 1 above is acquired by marking the nearest neighbor to each of all pixel points from (0, 0) to (u, v) in a depth map of a size of u×v, as shown in FIG. 2(a).

As shown in FIG. 2(b), rows of the adjacency matrix indicate addresses of query points, and columns of the adjacency matrix indicate the nearest neighbors at the query points.

That is, the band matrix conversion unit 100 converts the adjacency matrix into a band matrix using the rows of the adjacency matrix as addresses of query points and the columns of the adjacency matrix as the nearest neighbors at the query points.

The nearest neighbors are acquired using a K-nearest neighbor (KNN) algorithm.

At this time, the K-nearest neighbor algorithm is performed in units of a window to limit a search area. Since near neighbors are marked in the search area, therefore, the adjacency matrix is shown in a band form.

For example, when the horizontal and vertical sizes of a window are 4 and 4, as shown in FIG. 2, four bands are marked in the adjacency matrix in the vertical direction, and four ingredients are marked in each band in the horizontal direction.

When four nearest neighbors are found based on query point QA, nearest points A₀, A₁, A₂, and A₃ may be found in a window of 4×4. If the nearest neighbor is marked for each row of the window, as shown in FIG. 2, one ingredient is marked in each band of the adjacency matrix.

The band matrix compression unit 200 marks an index on each band in order to compress the band matrix converted by the band matrix conversion unit 100.

That is, the band matrix compression unit 200 marks band indices using D0, D1, D2, and D3, as shown in FIG. 2(b), and stores the information in the register 300.

The band matrix compression unit 200 removes a value of 0 from matrix ingredients belonging to the bands through run-length encoding, performs one compression, as shown in FIG. 2(c), and stores index values marking the same in the register 300.

Through the above compression, the band matrix compression unit 200 greatly compresses data in a state of being finally divided into a 3-bit band index, 16-bit nonzero ingredient data, and a 4-bit nonzero ingredient index.

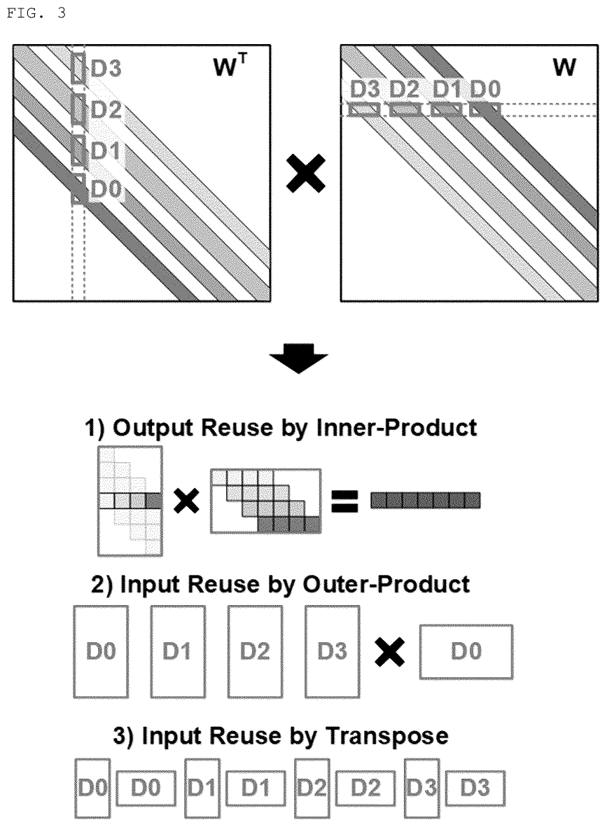

Meanwhile, as shown in FIG. 3, the band matrix calculation unit 400 performs computation of the band matrix W converted by the band matrix conversion unit 100 and computation of a transposed band matrix W^{T} with respect to the band matrix.

The band matrix calculation unit 400 performs computation of the band matrix W and computation of the transposed band matrix W^{T} in units of a tile and performs multiplication therebetween by outer product in order to increase the data reuse rate during matrix computation.

Consequently, the band matrix calculation unit 400 performs outer-product computation of multiplying the tile of the transposed band matrix W^{T} in the vertical direction by the tile of the band matrix W in the horizontal direction.

Since the band matrix calculation unit 400 loads tile data D3 of the band material from the memory unit 500 so as to be multiplied by tile data D3, D2, D1, and D0 of the transposed band matrix W^{T} through the outer-product computation, it is possible to reuse the tile data.

At this time, the band matrix calculation unit 400 multiplies ingredients by inner product during multiplication between the tiles, whereby it is possible to accumulate multiplied output values, and therefore it is possible to reuse output data.

Since the band matrix W and the transposed band matrix are disposed in point symmetry, the band matrix W^{T} calculation unit 400 loads the tile data D0, D1, D2, and D3 of the band matrix from the memory unit 500 and multiplies the same by D0, D1, D2, and D3 of the transposed band matrix, whereby it is possible to perform multiplication between the two matrices without additional memory access.

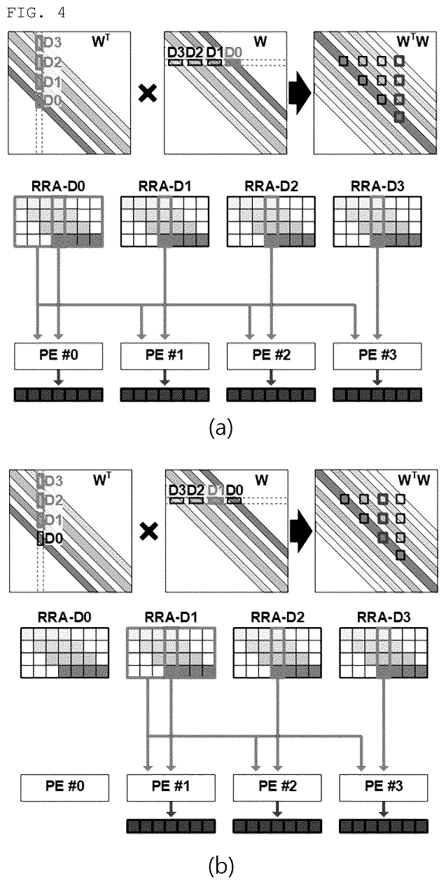

Meanwhile, in order to perform efficient computation, it is necessary to decode the compressed data of the band matrix. Hereinafter, decoding of the compressed data of the band matrix will be described with reference to FIG. 4.

First, the band matrix calculation unit 400 recovers the compressed data and sequentially stores the same so as to correspond to a routing register array (RRA) 410 corresponding to each band index. Computation of FIG. 3 is performed using routing register arrays RRA-D0, RRA-D1, RRA-D2, and RRA-D0 indicating the respective bands.

First, as shown in FIG. 4(a), the band matrix calculation unit 400 simultaneously transmits data of the routing register array RRA-D0 to processing elements PE #0, PE #1, PE #2, and PE #3 in order to multiply D0 of the band matrix W by D0, D1, D2, and D3 of the transposed band matrix W^{T}.

Subsequently, as shown in FIG. 4(b), the band matrix calculation unit 400 transmits ingredients corresponding to the middle column of the routing register array RRA-D0 to the processing element PE #0 in order to multiply the tile data D0 of the band matrix by the tile data D0 of the transposed band matrix.

Likewise, the band matrix calculation unit 400 transmits ingredients corresponding to the middle columns of the routing register arrays RRA-D1, RRA-D2, and RRA-D3 to the processing elements PE #1, PE #2, and PE #3, respectively, in order to multiply the tile data D0 of the band matrix by the tile data D0, D1, D2, and D3 of the transposed band matrix.

In order to multiply the tile data D1 of the band matrix by the tile data D1, D2, and D3 of the transposed band matrix in the same manner, as shown in FIG. 4(b), the band matrix calculation unit 400 simultaneously transmits data of the routing register array RRA-D1 to the processing elements PE #1, PE #2, and PE #3, and transmits ingredients corresponding to the middle column of each of the routing register arrays RRA-D1, RRA-D2, and RRA-D3 to a corresponding one of the processing elements PE #1, PE #2, and PE #3 in order to perform tile data multiplication.

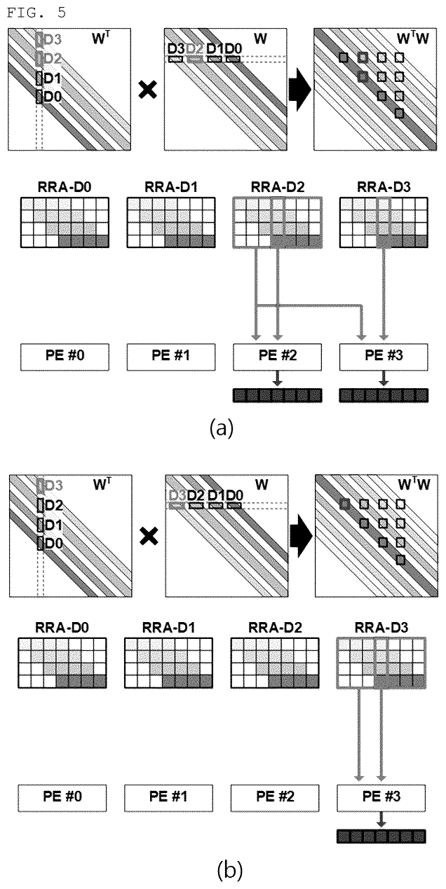

In order to multiply the tile data D2 of the band matrix by the tile data D2 and D3 of the transposed band matrix in the same manner, as shown in FIG. 5(a), the band matrix calculation unit 400 simultaneously transmits data of the routing register array RRA-D2 to the processing elements PE #2 and PE #3, and transmits ingredients corresponding to the middle column of each of the routing register arrays RRA-D2 and RRA-D3 to a corresponding one of the processing elements PE #2 and PE #3 in order to perform tile data multiplication.

Finally, in order to multiply the tile data D3 of the band matrix by the tile data D3 of the transposed band matrix, as shown in FIG. 5(b), the band matrix calculation unit 400 transmits data of the routing register array RRA-D3 to the processing element PE #3, and transmits ingredients corresponding to the middle column of the routing register arrays RRA-D3 to the processing element PE #3 in order to perform tile data multiplication.

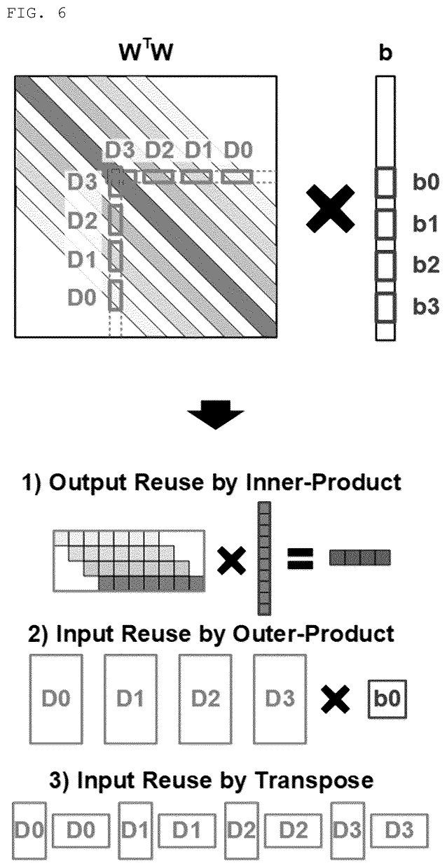

Meanwhile, the band matrix calculation unit 400 multiplies a symmetric band matrix W^{T}W by a vector b using a computation method shown in FIG. 6.

In order to increase the data reuse rate during computation between the matrix and the vector, the band matrix calculation unit 400 multiplies an upper tile and a lower tile of the symmetric band matrix based on the main diagonal line thereof by a vector tile by outer product.

Consequently, the band matrix calculation unit 400 multiplies the upper tile of the symmetric band matrix W^{T}W in the vertical direction and the lower tile of the symmetric band matrix W^{T}W in the horizontal direction by the vector tile.

Since the band matrix calculation unit 400 loads a vector tile b0 from the memory unit 500 so as to be multiplied by lower tile data D3, D2, D1, and D0 of the symmetric band matrix W^{T}W through the outer-product computation, it is possible to reuse the tile data.

In addition, the band matrix calculation unit 400 multiplies ingredients by inner product during multiplication between the tiles, whereby it is possible to accumulate multiplied output values, and therefore it is possible to reuse output data.

Furthermore, since the symmetric band matrix W^{T}W has a point symmetric structure based on the main diagonal line thereof, the band matrix calculation unit 400 loads the upper tile data D0, D1, D2, and D3 of the symmetric band matrix W^{T}W from the memory unit 500 and multiplies the same by the vector tile, and at the same time multiplies the lower tile data D0, D1, D2, and D3 of the symmetric band matrix W^{T}W by the vector tile whereby it is possible to perform multiplication between the matrix and the vector without additional memory access.

Meanwhile, in order for the band matrix calculation unit 400 to perform efficient computation, it is necessary to decode the compressed data of the band matrix.

As shown in FIG. 6, the band matrix calculation unit 400 recovers the compressed data through decoding and sequentially stores the same so as to correspond to a routing register array (RRA) corresponding to each band index. However, only an upper matrix part is recovered and used due to symmetry of the symmetric band matrix.

Computation of FIG. 6 is performed using routing register arrays RRA-D0, RRA-D1, RRA-D2, and RRA-D0 indicating the respective bands.

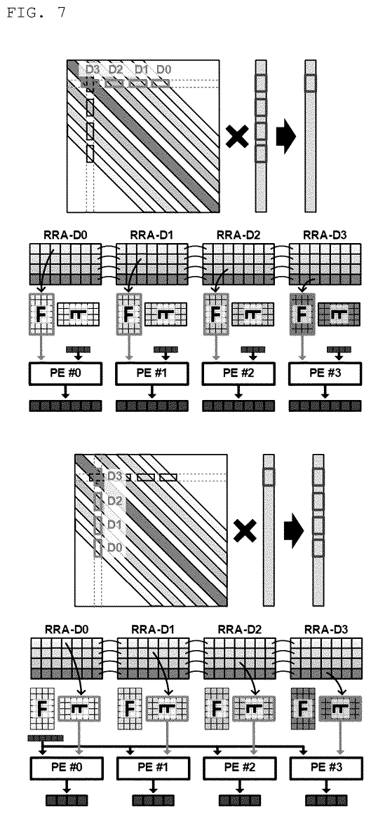

First, in order to multiply the upper tile data D0, D1, D2, and D3 of the symmetric band matrix by vector tiles b0, b1, b2, and b3, as shown in FIG. 7, the band matrix calculation unit 400 transmits all data of the routing register arrays RRA-D0, RRA-D1, RRA-D2, and RRA-D3 to the processing elements PE #0, PE #1, PE #2, and PE #3, respectively, and transmits the vector files to the respective processing elements PE to perform computation of the matrix and the vector.

Also, in order to multiply the lower tile data D0, D1, D2, and D3 of the symmetric band matrix by the vector tile b0, the band matrix calculation unit 400 transmits all data of the routing register arrays RRA-D0, RRA-D1, RRA-D2, and RRA-D3 respectively to the processing elements PE in point symmetry, and simultaneously transmits the vector tile b0 to the processing elements PE #0, PE #1, PE #2, and PE #to perform multiplication between the matrix and the vector.

The conjugate gradient acceleration apparatus using band matrix compression in depth fusion technology according to the present invention uses a method of correcting depth data acquired from data of the image sensor through deep learning based on depth information acquired from the depth sensor, whereby it is possible to perform depth fusion with respect to the depth data acquired from the image sensor irrespective of the resolution of the depth sensor and the number of pixels.

In addition, when physical movement of the image sensor is not great and when the movement of a target object is not great, depth information is not greatly changed, whereby it is possible to perform depth fusion in the state in which the depth sensor is intermittently activated, and therefore it is possible to further reduce sensor power consumption.

As is apparent from the above description, a conjugate gradient acceleration apparatus using band matrix compression in depth fusion technology according to the present invention has an effect in that it is possible to greatly compress a band matrix, to greatly reduce the external memory access bandwidth required when a conjugate gradient method is performed, and to greatly reduce the number of required inner memory accesses, whereby it is possible to greatly reduce total computation time.

In addition, the conjugate gradient acceleration apparatus using band matrix compression in depth fusion technology according to the present invention has an effect in that it is possible to greatly reduce the size of an adjacency matrix used when the conjugate gradient method is performed to compress the band matrix from 703 MB to 0.472 MB and to achieve compressibility 32.6% higher than in a conventional compressed sparse row method.

In addition, the conjugate gradient acceleration apparatus using band matrix compression in depth fusion technology according to the present invention has an effect in that it is possible to further compress a symmetric band matrix since symmetric area data are not stored, to greatly reduce the size of the symmetric band matrix used when the conjugate gradient method is performed from 703 MB to 0.735 MB, and to achieve compressibility 60.5% higher than in the conventional compressed sparse row method.

In addition, the conjugate gradient acceleration apparatus using band matrix compression in depth fusion technology according to the present invention has an effect in that a band matrix calculation unit is designed to maximally reuse data without memory access when the band matrix is computed, whereby it is possible to greatly reduce the amount of data that are moved.

In addition, the conjugate gradient acceleration apparatus using band matrix compression in depth fusion technology according to the present invention has an effect in that a data movement amount of 125.9 MB/Frame is generated when no band matrix calculation unit is provided, whereas a data movement amount of 64.5 MB/Frame is generated when the band matrix calculation unit is used, and therefore it is possible to reduce the amount of data that are moved by 48.8%, and it is possible to reduce operation speed of a depth fusion algorithm by 53.1% from 16.0 ms to 7.5 ms due thereto.

Although the technical idea of the present invention has been described above with reference to the accompanying drawings, this exemplarily explains preferred embodiments of the present invention but does not limit the present invention. In addition, it is obvious to a person having ordinary skill in the art to which the present invention pertains that various modifications and alterations are possible without departing from the category of the technical idea of the present invention.

What is claimed is:

1. A conjugate gradient acceleration apparatus using band matrix compression in depth fusion technology, the conjugate gradient acceleration apparatus comprising:
a band matrix conversion unit configured to convert an adjacency matrix for correcting depth data acquired from data of an image sensor through deep learning based on depth information acquired from a depth sensor into a band matrix using rows of the adjacency matrix as addresses of query points and columns of the adjacency matrix as the nearest neighbors at the query points;
a band matrix compression unit configured to mark an index on each band in order to compress the band matrix converted by the band matrix conversion unit and to compress data in a state of being divided into a predetermined bit band index, predetermined bit nonzero ingredient data, and another predetermined bit nonzero ingredient index;
a memory unit configured to store tile data of the band matrix; and
a band matrix calculation unit configured to perform computation of the band matrix and a transposed band matrix or computation of a symmetric band matrix with respect to the band matrix and a vector.

2. The conjugate gradient acceleration apparatus according to claim 1, wherein the band matrix compression unit performs compression to remove a value of 0 from matrix ingredients belonging to bands of the band matrix through run-length encoding.

3. The conjugate gradient acceleration apparatus according to claim 2, wherein the band matrix calculation unit performs computation of the band matrix and computation of the transposed band matrix in units of a tile and reuses data by using a routing register array through outer-product computation between tiles, which multiplies the tiles, without memory access.

4. The conjugate gradient acceleration apparatus according to claim 3, wherein, when the band matrix and the transposed band matrix are computed, the band matrix calculation unit computes ingredients in the tiles by reusing middle data in the routing register array through inner-product computation.

5. The conjugate gradient acceleration apparatus according to claim 2, wherein the band matrix calculation unit performs computation of the symmetric band matrix with respect to the band matrix and the vector in units of a tile and reuses data by using a routing register array through outer-product computation between tiles, which multiplies the tiles, without memory access.

6. The conjugate gradient acceleration apparatus according to claim 5, wherein, when the symmetric band matrix and the vector are computed, the band matrix calculation unit computes ingredients in the tiles by reusing middle data in the routing register array through inner-product computation.

7. The conjugate gradient acceleration apparatus according to claim 1, wherein the band matrix calculation unit always activates the depth sensor based on purposes and power consumption conditions to receive depth information in order to perform depth fusion with the image sensor, activates the depth sensor for a predetermined time at predetermined intervals to periodically perform depth fusion, or intermittently activates the depth sensor as needed to perform depth fusion.
